(19) United States
(12) Patent Application Publication
(10) Pub. No.: US 2025/0137855 A1
(43) Pub. Date: May 1, 2025

(54) Calibration Techniques for Temperature Sensors

(71) Applicant: Arm Limited, Cambridge (GB)

(72) Inventors: Tirdad Anthony Takeshian, Vence (FR); El Mehdi Boujamaa, Valbonne (FR); Amit Chhabra, Delhi (IN); Rainer Herberholz, Great Abington (GB)

(21) Appl. No.: 18/926,154

(22) Filed: Oct. 24, 2024

(30) Foreign Application Priority Data
Oct. 27, 2023 (IN) 202341073192
Feb. 28, 2024 (GB) 2402808.6

(51) Int. Cl. G01K 19/00; G01K 7/20; G01K 7/24

(52) U.S. Cl. CPC G01K 19/00; G01K 7/203; G01K 7/245

(57) ABSTRACT

Various implementations described herein are directed to a method that acquires operating frequencies for a first set of ring oscillators disposed in a first integrated circuit, determines one or more first coefficients and a first constant for each ring oscillator in the first set, and determines a correlation between each of the first coefficients and the first constant. Also, the method may acquire a single operating frequency for each of a second set of ring oscillators in a second integrated circuit at a single pre-determined temperature so as to determine a second constant, predict one or more second coefficients for each ring oscillator in the second set based on the second constant and the correlation, and derive a temperature dependence based on the single operating frequency using the one or more second coefficients and the second constant for each of the second set of ring oscillators.

### BACKGROUND

This section is intended to provide information relevant to understanding the various technologies described herein. As the section's title implies, this is a discussion of related art that should in no way imply that it is prior art. Generally, related art may or may not be considered prior art. It should therefore be understood that any statement in this section should be read in this light, and not as any admission of prior art.

In modern circuit architectures, multiple points of temperature measurements are typically needed to calibrate temperature sensors. Thus, area deficiencies can arise in some circuit applications when implementing conventional calibration techniques due to the need for multiple temperature sensors and multiple temperature measurements for each temperature sensor. Thus, there exists a need to improve traditional circuit designs in many modern circuit applications by providing more effective and/or efficient calibration schemes for temperature sensor related applications in physical circuit designs.

### BRIEF DESCRIPTION OF THE DRAWINGS

Implementations of various techniques are described herein with reference to the accompanying drawings. It should be understood, however, that the accompanying drawings illustrate only various implementations described herein and are not meant to limit embodiments of various techniques described herein.

FIG. 1 illustrates a diagram of temperature sensor architecture in accordance with various implementations described herein.

FIG. 2 illustrates a diagram of thermal sensor circuitry having a ring oscillator configuration in accordance with various implementations described herein.

FIG. 3 illustrates a diagram of a digital temperature sensor in accordance with various implementations described herein.

FIG. 4A illustrates a diagram of pseudo two-point calibration techniques in accordance with various implementations described herein.

FIG. 4B illustrates a diagram of pseudo two-point calibration techniques in accordance with various implementations described herein.

FIG. 4C illustrates a diagram of pseudo two-point calibration techniques in accordance with various implementations described herein.

FIG. 5 illustrates a diagram of a central processing unit (CPU) having thermal sensor architecture in accordance with various implementations described herein.

FIG. 6 illustrates diagrams of methods for learning and usage techniques for temperature sensors in accordance with implementations described herein.

FIG. 7 illustrates a process diagram of a method for calibrating a temperature sensor in accordance with various implementations described herein.

### DETAILED DESCRIPTION

Various implementations described herein relate to various calibration schemes and techniques for temperature sensor related applications in physical designs. Also, in some implementations, the calibration schemes and techniques for temperature sensors described herein provide for a digital temperature sensor with pseudo multi-point (e.g., 2-point) calibration that may be used in various circuit applications.

In order to precisely monitor the temperature of a running CPU, a temperature sensor which can be placed inside the CPU is desirable. The most compatible sensor would therefore be a “digital temperature sensor” which is based on standard cells (i.e. inverters, NAND, NOR) connected in a ring oscillator (RO) configuration. The frequency of this RO is proportional to temperature. However, frequency vs temperature characteristic is highly dependent on multiple variables, such as voltage, and especially the process. The temperature interpretation is extracted from the RO frequency, the frequency temperature relationship must be well known. One typical way to obtain this is by performing a “2 point calibration”, i.e. measuring the frequency at two different temperatures. This is an expensive process because the ring oscillators which are disposed on the integrated circuits have to be brought at different temperatures during the fabrication process and the time needed to stabilize the temperature of these integrated circuits can be in the order of minutes.

Our proposed solution solves this problem by exploiting the fact that the frequency of a RO is correlated with its slope with respect to temperature. Therefore, after technology characterization, one can extract a temperature response of a ring oscillator and have a two points equivalent calibration at a single temperature. The calibration becomes cheaper, and a precise temperature measurement can still be obtained with a simple one point calibration. Hence the name “pseudo two points” calibration.

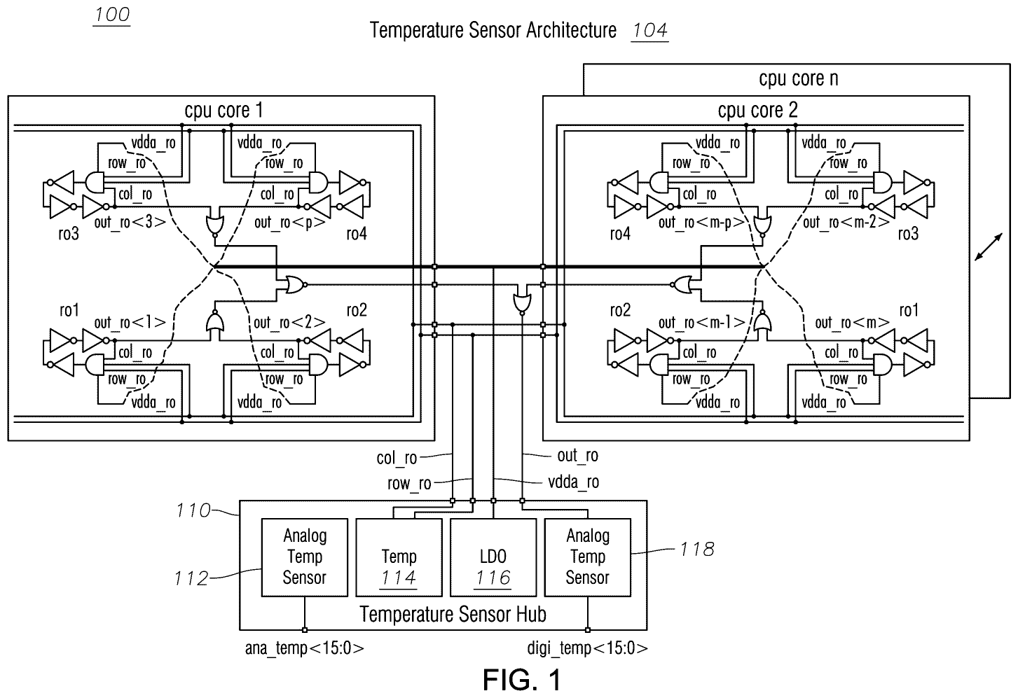

Various implementations of calibration schemes and techniques in reference to temperature sensors will now be described herein in FIGS. 1-7.

FIG. 1 illustrates a schematic diagram 100 of temperature sensor architecture 104 in accordance with various implementations described herein.

In some implementations, the temperature sensor architecture 104 may provide for calibrating temperature sensor circuitry with various integrated circuit (IC) components that may be arranged and/or coupled together as an assemblage or some combination of parts that may provide for physical circuit designs and/or structures. In some instances, a method of designing, providing and fabricating the temperature sensor architecture 104 as an integrated system or device may involve use of various circuit components and/or related structures described herein so as to implement the temperature sensor calibration techniques associated therewith. Also, the temperature sensor architecture 104 may be integrated with various circuitry and/or related components on a single chip, and also, the temperature sensor architecture 104 may be implemented in some embedded devices for automotive, mobile, computer, server and/or Internet-of-Things (IoT) based applications, including, e.g., remote sensor nodes.

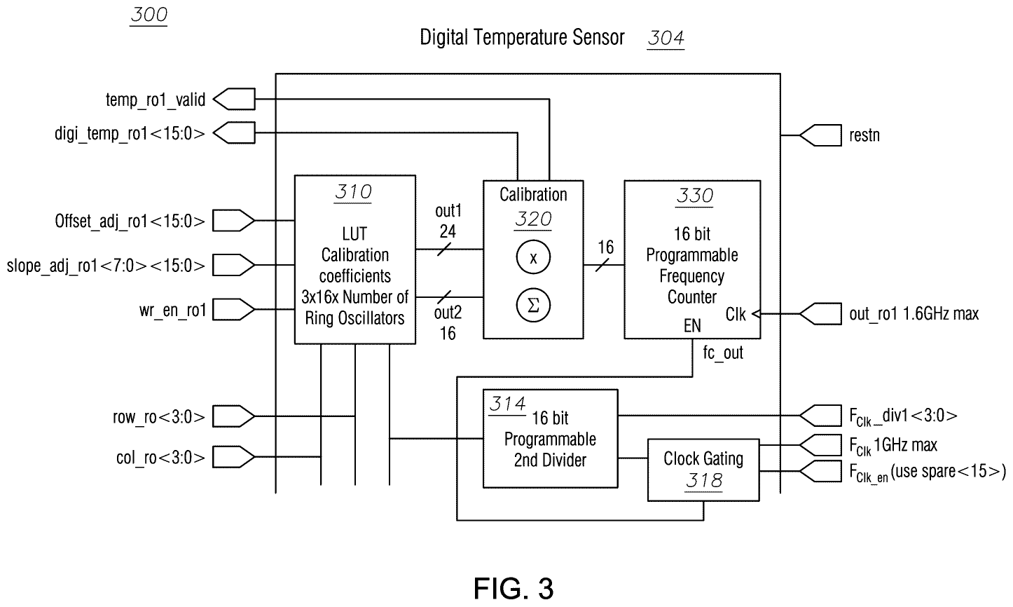

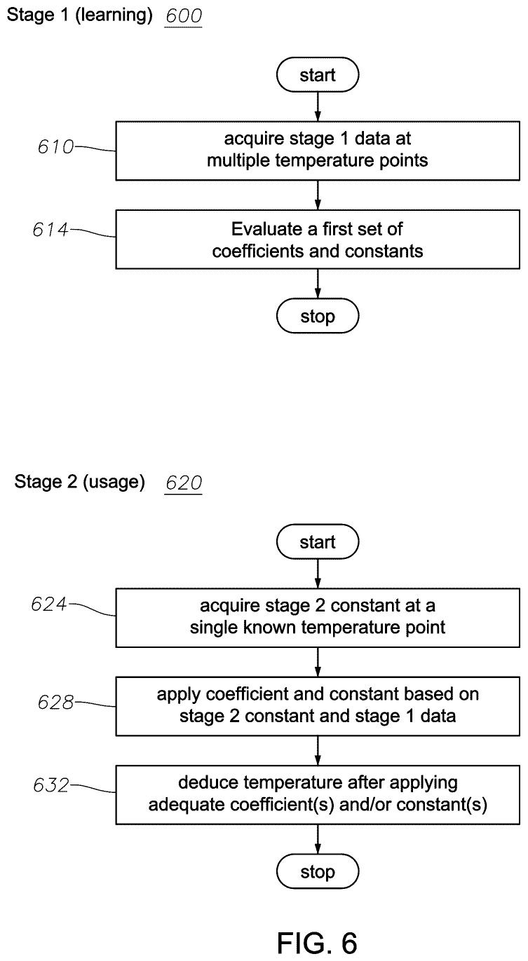

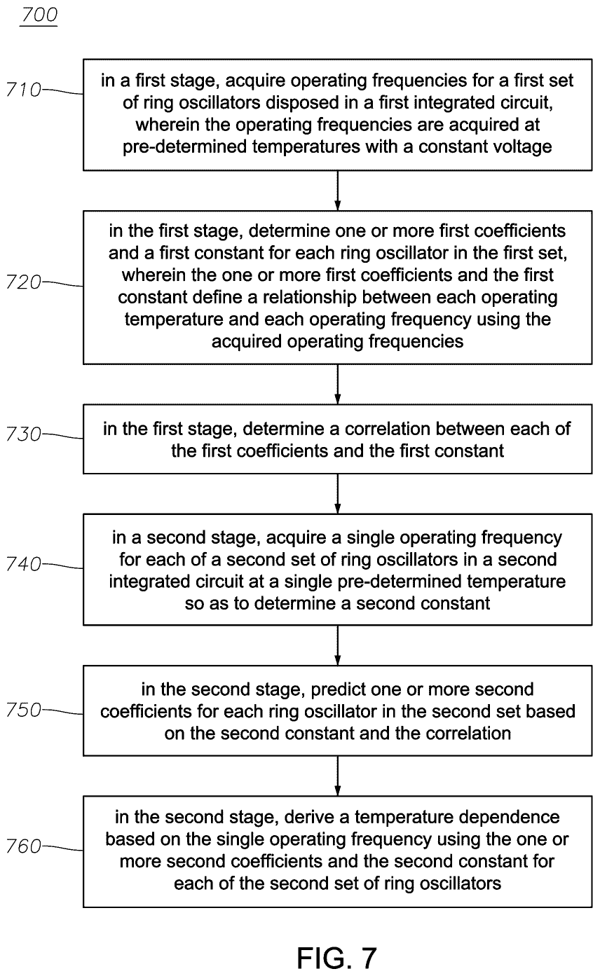

As shown in FIG. 1, the temperature sensor structure or architecture 104 may include various components, including, e.g., a number (n) of central processing unit (CPU) cores (cpu core 1, cpu core 2, . . . , cpu core n) and a temperature sensor hub 110. Also, in some applications, the temperature sensor hub 110 may include various components, including, e.g., an analog temperature sensor 112, a logic circuit 114, a load drop-out (LDO) regulator 116, and a digital temperature sensor 118 that are arranged and coupled together so as to generate and provide a pseudo 2-point calibration associated with one or more of the ring oscillators (ro1, ro2, ro3, ro4) within each CPU core (cpu core 1, cpu core 2, . . . , cpu core n). Also, various aspects related to the digital temperature sensor 118 are described in greater detail herein in reference to FIG. 3 and also in reference to performing the methods as described in reference to FIGS. 6-7.

In some implementations, each central processing unit (CPU) cores (cpu core 1, cpu core 2, . . . , cpu core n) may have a plurality of temperature sensors, such as, e.g., ring oscillators (ro1, ro2, ro3, ro4) that are arranged and coupled together so as to provide temperature at different areas, portions and/or segments within the CPU core circuitry of each CPU core (cpu core 1, cpu core 2, . . . , cpu core n). Also, as shown, the ring oscillators (ro1, ro2, ro3, ro4) within each CPU core (cpu core 1, cpu core 2, . . . , cpu core n) may be coupled together by way of logic gates, such as, e.g., NOR gates, and also, output signals (out_ro<1>, out_ro<2>, out_ro<3>, out_ro<p> and out_ro<m>, out_ro<m-1>, out_ro<m-2>, out_ro<m-p>) of the ring oscillators (ro1, ro2, ro3, ro4) may be coupled to the logic gates (e.g., NOR gates) within each CPU core (cpu core 1, cpu core 2, . . . , cpu core n) may be coupled together by way of another logic gate so as to provide an out_ro signal the temperature sensor hub 110.

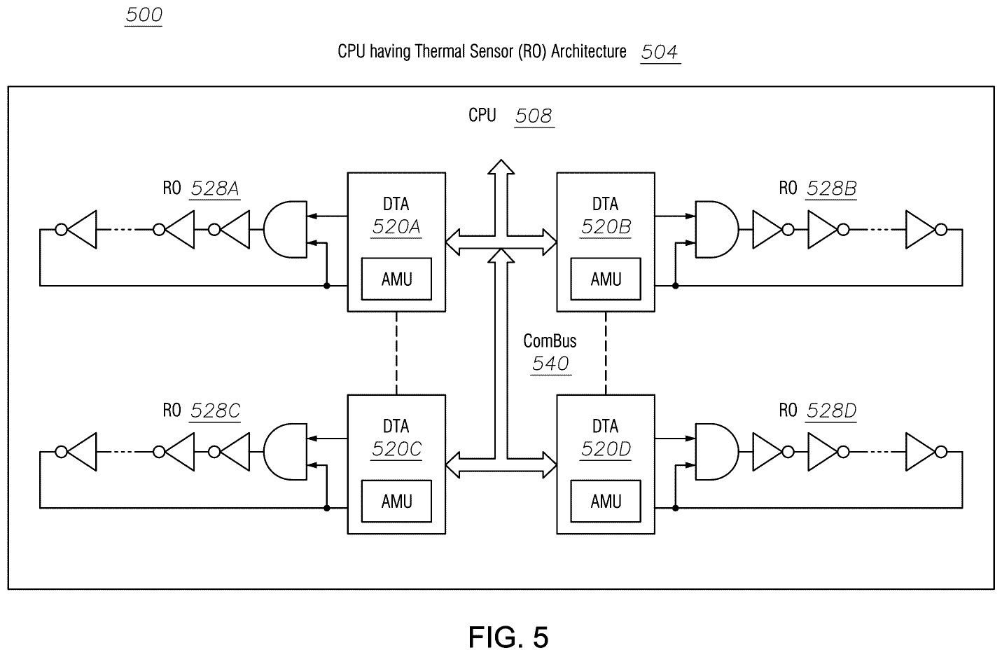

In some implementations, the CPU cores (cpu core 1, cpu core 2, . . . , cpu core n) may include a first CPU core (cpu core 1) as a first integrated circuit having a first set of ring oscillators (e.g., ro1, ro2, ro3, ro4) with a first number (p) of ring oscillators. Also, the CPU cores (cpu core 1, cpu core 2, . . . , cpu core n) may include a second CPU core (cpu core 1) as a second integrated circuit having a second set of ring oscillators (e.g., ro1, ro2, ro3, ro4) with a second number (m) of ring oscillators. For sake of simplicity, each cpu core may include multiple (e.g., 4) ring oscillators; however, each cpu core may have any number of ring oscillators in various applications. Also, additional scope related to features and components of the CPU cores (cpu core 1, cpu core 2, . . . , cpu core n) are described in greater detail herein in reference to FIG. 5.

In some implementations, the temperature sensor hub 110 may include various components, including, e.g., an analog temperature sensor 112, a logic circuit 114, a load drop-out (LDO) regulator 116, and a digital temperature sensor 118 that are arranged and coupled together so as to generate and/or provide a pseudo 2-point calibration associated with one or more of the ring oscillators (ro1, ro2, ro3, ro4) within each CPU core (cpu core 1, cpu core 2, . . . , cpu core n). Also, the analog temperature sensor 112 may be used to sense an actual temperature (ana_temp<15:0>) so as to thereby compare to a calculated temperature. Also, the logic circuit 114 may provide column select signals (col_ro) and/or row select signals (row_ro) to each ring oscillator (ro1, ro2, ro3, ro4) within each CPU core (cpu core 1, cpu core 2, . . . , cpu core n). Also, the load drop-out (LDO) regulator 116 may provide voltage signals (vdda_ro) to each ring oscillator (ro1, ro2, ro3, ro4) within each CPU core (cpu core 1, cpu core 2, . . . , cpu core n). Also, the digital temperature sensor 118 may receive the out_ro signal from the logic gates of the ring oscillators (ro1, ro2, ro3, ro4) within each CPU core (cpu core 1, cpu core 2, . . . , cpu core n) and then provide a digital temperature (digi_temp<15:0>).

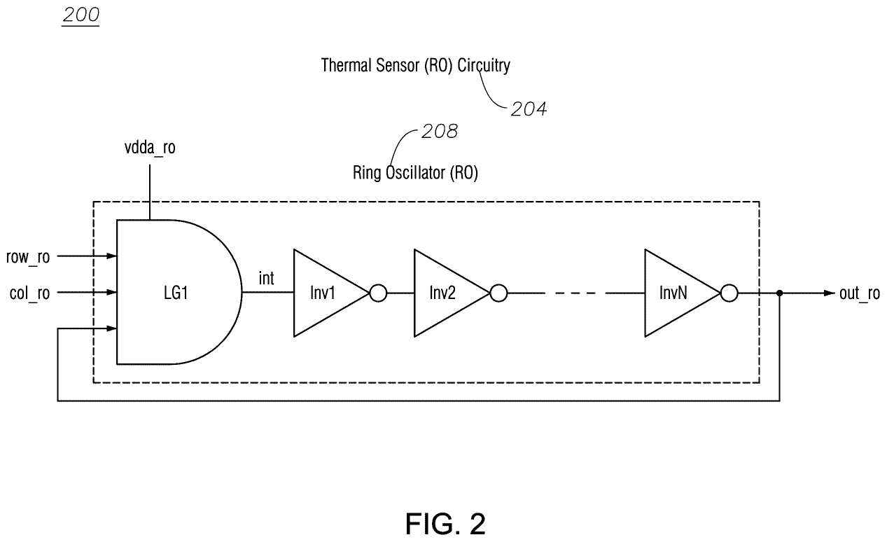

Also, additional scope related to features and components of the ring oscillators (ro1, ro2, ro3, ro4) in reference to the CPU cores (cpu core 1, cpu core 2, . . . , cpu core n) are described in greater detail herein in reference to FIGS. 2 and 5. Also, additional scope related to features, behaviors and/or components of the digital temperature sensor 118 are described in greater detail herein in reference to FIG. 3 and also in reference to performing the methods as described in reference to FIGS. 6-7.

In some implementations, the load drop-out regulator (LDO regulator) 116 may refer to a DC linear voltage regulator that may be used to regulate the output voltage even when the supply voltage is close to the output voltage. Also, in various applications, the analog temperature sensor 112 refers to an optional component.

FIG. 2 illustrates a diagram 200 of thermal sensor circuitry 204 having a ring oscillator (RO) configuration 208 in accordance with implementations described herein.

As shown in FIG. 2, the thermal sensor circuitry 204 may be configured as a ring oscillator (RO) 208 that operates as performance sensing circuitry for providing output oscillating frequencies related to detecting variation of performance of a set of inverters, such as, e.g., Inv1, Inv2, . . . , InvN. Thus, the ring oscillator (RO) 208 may provide the set of inverters (Inv1, Inv2, . . . , InvN) as an inverter delay stage that is adapted to provide the output oscillating frequency (out_ro) as an output RO signal.

In some implementations, the ring oscillator (RO) 208 may include the inverter delay stage, e.g., set of inverters (Inv1, Inv2, . . . , InvN), interposed between an input logic gate (LG1), such as, e.g., an AND gate, and the output (out_ro). In various instances, the inverter delay stage (Inv1, Inv2, . . . , InvN) may include any number of inverter stages that are coupled in series, with only one condition in that the ring oscillator (RO) 208 provides the oscillating output signal (out_ro). The inverter delay stage (Inv1, Inv2, . . . , InvN) may provide the output oscillating signal (out_ro) as a feedback signal to the input logic gate (LG1), which receives multiple input signals, e.g., including the row_ro signal, the col_ro signal, and the output oscillating signal (out_ro) as a feedback input signal. As such, the input logic gate (LG1) receives input signals (row_ro, col_ro, out_ro), receives the vdda_ro signal from LDO 116, and then provides an intermediate signal (int) to the inverter delay stage (Inv1, Inv2, . . . , InvN). Also, in various applications, the input logic gate (LG1) may be implemented with different logic gates, including, e.g., AND/NAND gates, OR/NOR gates, etc. In other instances, the inverter delay stage may be implemented with any other logic structure that provides an inverting output, such as, e.g., using various logic stages. Also, in still other instances, the ring oscillator (RO) 208 may be any other type of voltage controlled oscillator that provides similar behavior and/or characteristics.

FIG. 3 illustrates a schematic diagram 300 of a digital temperature sensor 304 in accordance with various implementations described herein. In some applications, the digital temperature sensor 118 shown in FIG. 1 may be implemented with the digital temperature sensor 304 shown in FIG. 3.

In some implementations, the digital temperature sensor 304 may be referred to as a digital temperature analyzer, wherein an oscillator together with the block 304 may be implemented as a temperature sensor or analyzer, such that temperature dependence of the ring oscillator (RO) is exploited so as to have temperature sensing capabilities.

As shown in FIG. 3, the digital temperature sensor 304 may include various components, including, e.g., a look-up table (LUT) 310, a calibration circuit 320 (with multiplier and summation), and a frequency counter 330. In some implementations, the look-up table (LUT) 310 may comprise a memory device that stores calibration coefficients, such as, e.g., the first and second coefficients, for calibrating the temperature sensors in reference to the CPU cores. Also, the look-up table (LUT) 310 may include a divider circuit 314 and a clock gating circuit 318.

In some implementations, the look-up table (LUT) 310 may receive input signals, such as, e.g., a rest signal (restn), an offset adjust signal (offset_adj_ro1), a slope adjust signal (slope_adj_ro1), a write enable signal (wr_en_ro1), a row select signal (row<3:0>), a column select signal (col_ro<3:0>), a clock divider signal (Fck_div1<3:0>), a clock frequency signal (Fck_freq_max), and a clock enable signal (Fck_en). Also, the look-up table (LUT) 310 may provide one or more output signals, such as, e.g., a 24-bit output signal (out1) and/or a 16-bit output signal (out2), to the calibration circuit 320.

In some implementations, the frequency counter 330 may receive input signals, such as, e.g., a clock output signal (clk_out_ro1) and/or an enable signal (en). Also, the frequency counter 330 may provide one or more output signals, such as, e.g., a frequency output signal (fc_out), to the calibration circuit 320.

In some implementations, the calibration circuit 320 may receive input signals, such as, e.g., the 24-bit output signal (out1), the 16-bit output signal (out2), from the look-up table (LUT) 310. Also, the calibration circuit 320 may receive one or more other input signals, such as, e.g., the frequency counter signal (fc_out), from the frequency counter 330. Also, the calibration circuit 320 may provide one or more output signals, such as, e.g., a digital temperature signal (dig_temp <15:0>) having multiple bits and/or a temperature validation signal (temp_ro1_valid).

In various applications, in reference to FIG. 3, the digital temperature sensor 304 may be referred to as a digital temperature analyzer having a memory circuit and an arithmetic block. In some implementations, the digital temperature analyzer may include a memory circuit having a look-up table (LUT) configured to store one or more first coefficients and a first constant for each ring oscillator. Also, the one or more first coefficients and the first constant may be used to define a relationship between operating temperatures and operating frequencies based on previously acquired operating frequencies at pre-determined temperatures with a constant voltage for a first set of ring oscillators. Also, in some implementations, the digital temperature analyzer may include an arithmetic block that performs a calibration by acquiring a single operating frequency for each of a second set of ring oscillators at a single pre-determined temperature so as to determine a second constant and based on the second constant applies the one or more first coefficients and the first constant from the look-up table (LUT) so as to derive a correct temperature. Also, in some implementations, the pre-determined temperatures may comprise at least a first pre-determined temperature and a second pre-determined temperature, and in addition, the operating frequencies may comprise at least a first operating frequency and a second operating frequency acquired at the first pre-determined temperature and the second pre-determined temperature and at the constant voltage. The digital temperature sensor as shown in FIG. 3 is one possible example implementation. However, any circuit which has a memory and an arithmetic block may be configured to perform the functions of the digital temperature sensor, for example, a dedicated CPU.

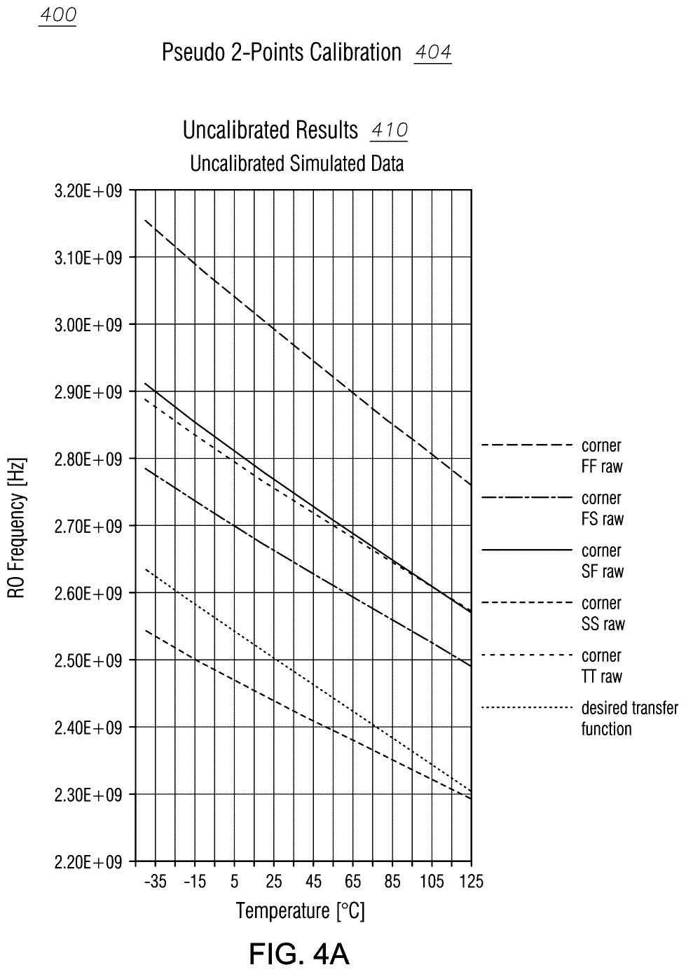

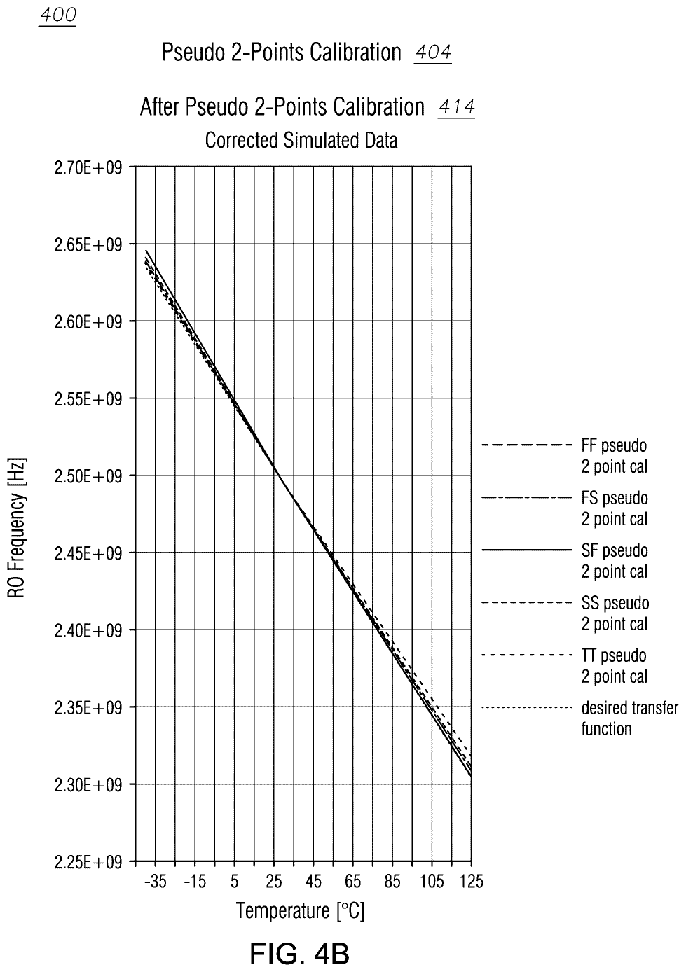

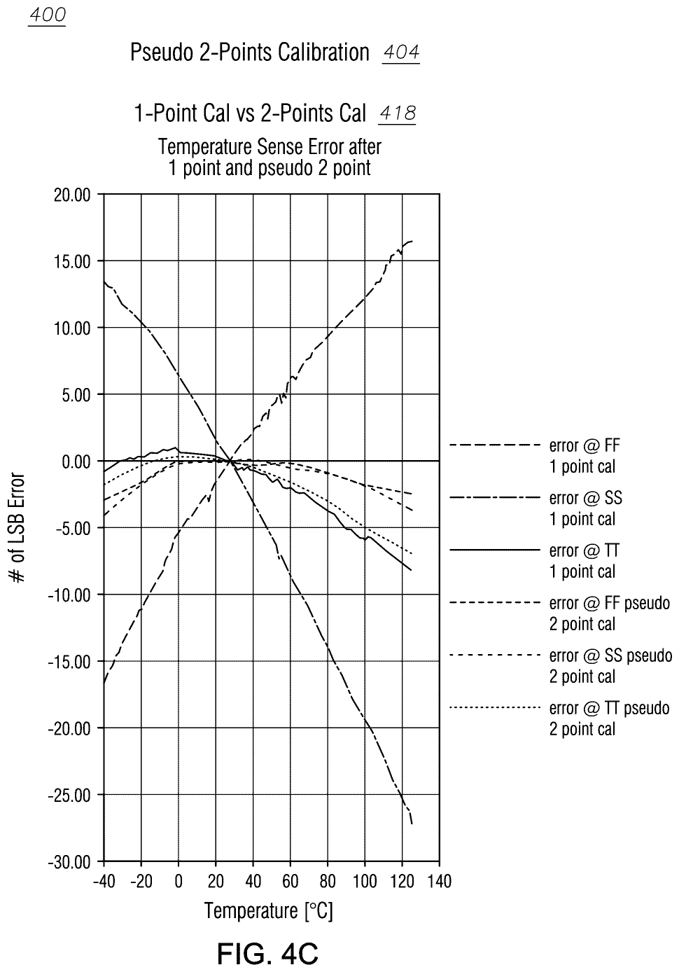

FIGS. 4A-4C illustrate various diagrams of pseudo two-point calibration techniques 404 in accordance with implementations described herein. In particular, FIG. 4A includes a first waveform diagram 410 showing uncalibrated results of temperature data, FIG. 4B includes a second waveform diagram 414 showing corrected temperature data after pseudo 2-points calibration of temperature data (e.g., at 27° C.), and FIG. 4C includes a third waveform diagram 414 showing temperature sense error for 1-point calibration versus 2-points calibration of temperature data.

As shown in FIG. 4A, the first waveform diagram 410 depicts temperature data in ° C. (x-axis) versus ring oscillator (RO) frequency (y-axis) in reference to the uncalibrated results of the temperature data associated with various process corners FF, FS, SF, SS, TT along with the desired transfer function. Also, in FIG. 4B, the second waveform 414 further depicts the corrected temperature data after pseudo 2-points calibration in reference to corrected results of the temperature data associated with various process corners FF, FS, SF, SS, TT along with the desired transfer function. Also, in FIG. 4C, the third waveform 418 further depicts the temperature sense error after 1-point calibration versus pseudo 2-points calibration of temperature data associated with various process corners FF, SS, TT. For instance, in reference to third waveform 418, shown is a 1-point calibration and 2-points calibration of the 1-point calibration −25° C./+15° C. 2-points calibration 0.5° C./−7° C. These numbers show a performance improvement.

FIG. 5 illustrates a diagram 500 of a central processing unit (CPU) 504 having thermal sensor architecture in accordance with implementations described herein.

As shown in FIG. 5, the CPU architecture 504 may include a CPU 508 having digital temperature analyzers (DTA) or sensors, including, e.g., 520A, 520B, 520C, 520D with each comprising an arithmetic and a memory unit (AMU) with each digital temperature analyzer (DTA) or sensor having at least one corresponding ring oscillator (RO) 528A, 528B, 528C, 528D coupled thereto. Also, in some instances, the CPU architecture 504 may include a communication bus (ComBus 540) that may be configured to communicate with the ring oscillator (RO) and/or interface with the digital temperature sensor and the CPU.

In various implementations, the CPU architecture 504 may be referred to as a CPU core comprising the plurality of the ring oscillators (RO) 528A, 528B, 528C, 528D disposed in different zones of the CPU core, and the CPU core may also comprise the digital temperature sensor or analyzer (DTA) 520A, 520B, 520C and 520D as shown in FIG. 5, which may be disposed near or wraps around each of the ring oscillators (RO) 528A, 528B, 528C, 528D. In some applications, the digital temperature analyzer (DTA) uses a supply voltage that is controlled by controlling a CPU voltage used by the CPU core. Also, in some applications, a selection of one or more of the plurality of ring oscillators (RO) 528A, 528B, 528C, 528D may be used to supply the voltage from the CPU core by way of the communication bus (ComBus 540) and/or a communication bus protocol (e.g., AXI, MSI bus, etc.).

In various implementations, the CPU architecture 504 (or CPU core) may have different temperatures in different zones of the CPU 508, and hence, the ring oscillators (RO) 528A, 528B, 528C, 528D may be disposed or incorporated throughout the CPU core where it matters (examples include vector units that may run or operate at high frequency and that heat-up significantly). Also, in some applications, the digital temperature sensor or analyzer (DTA) may use the CPU supply voltage, which may be achieved by making sure that the CPU core is not running. Hence, the voltage seen by the digital temperature sensor or analyzer (DTA) is preferably the CPU supply voltage, in some applications.

In various implementations, the CPU architecture 504 may be referred to as a system comprising a CPU core having the plurality of the ring oscillators (RO) 528A, 528B, 528C, 528D disposed in different zones of the CPU core. Also, the CPU architecture 504 may comprise the digital temperature sensor or analyzer (DTA) 304 as shown in FIG. 3, which may be disposed external to the CPU core. Also, in some applications, each ring oscillator (RO) 528A, 528B, 528C, 528D may be configured to use the digital temperature analyzer (DTA) independently. In various applications, the ring oscillators (RO) 528A, 528B, 528C, 528D may be sharing the digital temperature sensor or analyzer (DTA), which uses one at a time.

Also, the CPU architecture 504 may comprise a load drop-out unit (LDO) that controls a supply voltage provided to each ring oscillator (RO) 528A, 528B, 528C, 528D. Also, the CPU architecture 504 may comprise a logic block, such as, e.g., the logic circuit 114 as shown in FIG. 1, that is configured to select a ring oscillator (RO) 528A, 528B, 528C, 528D from the plurality of the ring oscillators that is using the digital temperature sensor or analyzer (DTA). In some applications, as shown in reference to FIG. 1, the digital temperature sensor (or analyzer) 118 and/or the logic circuit 114 may be configured to communicate with the LDO 116 in the temperature sensor hub 110. Also, as described in reference to FIG. 3, the digital temperature sensor (or analyzer) 304 may be used to implement the digital temperature sensor (or analyzer) 118 in FIG. 1.

In various implementations, the CPU architecture 504 may comprise (or at least be configured to use or interface with) the analog temperature sensor 112 of FIG. 1 as a reference analog temperature sensor. Thus, in some applications, the reference analog temperature sensor may provide at least one analog measured temperature, which may be compared with at least one temperature measurement provided by each ring oscillator (RO) 528A, 528B, 528C, 528D so as to determine whether each ring oscillator (RO) 528A, 528B, 528C, 528D provides a correct measured temperature.

FIG. 6 illustrates diagrams of methods for learning and usage techniques for temperature sensors in accordance with implementations described herein. In particular, FIG. 6 shows a stage 1 diagram 600 of a method for learning schemes and techniques related to temperature sensors, and FIG. 6 also shows a stage 2 diagram 620 of another method for usage schemes and techniques for temperature sensors.

It should be understood that even though methods 600, 620 indicate a particular order of operation execution, in some instances, various certain portions of the operations may be executed in a different order, and on different systems. In other cases, additional operations and/or steps may be added to and/or omitted from methods 600, 620. Also, the methods 600, 620 may be implemented in hardware and/or software. If implemented in hardware, the methods 600, 620 may be implemented with various components and/or circuitry, as described in FIGS. 1-5. Also, if implemented in software, methods 600, 620 may be implemented with program and/or software instruction processes configured for providing calibration schemes, techniques and applications, as described herein. Also, if implemented in software, instructions related to implementing methods 600, 620 may be stored in memory, such as a database. Also, in various applications, a computer or other various types of computing devices having a processor (e.g., CPU) and memory may be configured so as to thereby perform the methods 600, 620.

In some implementations, methods 600, 620 may be associated with a method for designing, providing, fabricating and/or manufacturing temperature sensor calibration schemes and techniques as an integrated system, device and/or circuit that involves use of circuit components and related structures described herein so as to implement various schemes and techniques associated therewith. Also, the various calibration schemes and techniques may be integrated with computing circuitry and related components on a single chip, and also, the calibration schemes and techniques may be implemented in embedded systems for various electronic, mobile and IoT applications.

In some applications, methods 600, 620 may refer to multiple stages including, e.g., a first stage (learning stage) 600 to perform a calibration and a second stage (usage stage) for using a correlation defined or determined in the first stage. Thus, the first stage may refer to a calibration (or learning) stage having blocks 610-614 that may be used for performing a calibration, and the second stage may refer to a correlation (or usage) stage having blocks 624-632 that may be used for utilizing the correlation defined or determined by the calibration (or learning) stage, in various applications.

At block 610, in the first stage, method 600 may acquire stage 1 data at multiple temperature points. Also, at block 614, in the first stage, method 600 may evaluate a first set of coefficients and/or constants. Also, at block 624, in the second stage, method 620 may acquire a stage 2 constant at a single known temperature point. Also, at block 628, in the second stage, method 620 may apply a coefficient and a constant based on the stage 2 constant and the stage 1 data. Also, at block 632, in the second stage, method 620 may deduce (or derive, or determine) a temperature, e.g., after applying one or more adequate coefficients and/or constants.

FIG. 7 illustrates a process flow diagram of a method 700 for calibrating a temperature sensor in accordance with various implementations described herein.

It should be understood that even though the method 700 indicates a particular order of operation execution, in some instances, various certain portions of the operations may be executed in a different order, and on different systems. In other cases, additional operations and/or steps may be added to and/or omitted from method 700. Also, method 700 may be implemented in hardware and/or software. If implemented in hardware, the method 700 may be implemented with various components and/or circuitry, as described herein in FIGS. 1-6. Also, if implemented in software, method 700 may be implemented with program and/or software instruction processes configured for providing temperature sensor calibration schemes, techniques and applications, as described herein. Also, if implemented in software, instructions related to implementing method 700 may be stored in memory, such as a database. Also, in various applications, a computer or other various types of computing devices having a processor, such as, e.g., CPU, and memory may be configured so as to thereby perform the method 700.

In some implementations, the method 700 may be associated with a method for designing, providing, fabricating and/or manufacturing temperature sensor calibration schemes and techniques as an integrated system, device and/or circuit that involves use of circuit components and related structures described herein so as to implement various schemes and techniques associated therewith. Also, the various calibration schemes and techniques may be integrated with computing circuitry and related components on a single chip, and also, the calibration schemes and techniques may be implemented in embedded systems for various electronic, mobile and IoT applications.

In some implementations, method 700 may have multiple stages including, e.g., a first stage for performing a calibration and a second stage for using a correlation defined or determined in the first stage. As such, the first stage may refer to a calibration stage having blocks 710-730 that may be used for performing a calibration, and also, the second stage may refer to a correlation stage having blocks 740-760 that may be used for utilizing the correlation defined or determined by the calibration stage.

At block 710, in the first stage, method 700 may acquire operating frequencies for a first set of ring oscillators disposed in a first integrated circuit, wherein the operating frequencies are acquired at pre-determined temperatures with a constant voltage. Also, the first integrated circuit may comprise one or more first integrated circuits, and each ring oscillator of the first set may be configured to operate as a temperature sensor. Also, the pre-determined temperatures may comprise at least a first pre-determined temperature and a second pre-determined temperature, and the operating frequencies may comprise at least a first operating frequency and a second operating frequency acquired at the first pre-determined temperature and the second pre-determined temperature and at the constant voltage. Also, the first pre-determined temperature may have a first temperature value that is approximately room temperature, such as, e.g., 25° C. Also, the second pre-determined temperature may have a second temperature value that is greater than or less than room temperature, such as, e.g., 25° C.

At block 720, in the first stage, method 700 may determine one or more first coefficients and a first constant for each ring oscillator in the first set, wherein the one or more first coefficients and the first constant define a relationship between each operating temperature and each operating frequency using the acquired operating frequencies. In various implementations, the relationship defined between the operating temperature and the operating frequency may be linear or non-linear. Also, in some implementations, the relationship defined between the operating temperature and the operating frequency may be a linear relationship that is further defined, e.g., by a slope and an intercept as a linear function to conduct measurements at only one temperature during the second stage.

At block 730, in the first stage, method 700 may determine (or define, or identify) a correlation between each of the first coefficients and the first constant.

At block 740, in a second stage, method 700 may acquire a single operating frequency for each of a second set of ring oscillators in a second integrated circuit at a single pre-determined temperature so as to determine a second constant. Also, in various applications, the second integrated circuit may comprise one or more second integrated circuits, and also, each ring oscillator of the second set may be configured to operate as a temperature sensor. Also, the first constant and the one or more first coefficients are used to correct for frequency variation between the one or more ring oscillators of the second set of ring oscillators in the second integrated circuits.

Also, the first pre-determined temperature may be the same as the single pre-determined temperature, and/or vice versa. Also, the single pre-determined temperature may comprise a third pre-determined temperature, and the single operating frequency may comprise a third operating frequency. Also, in the second stage, the third operating frequency may be acquired for each ring oscillator in the second set at the third pre-determined temperature so as to determine the second constant.

Also, in various implementations, the third temperature value may be between the first temperature value and the second temperature value. In other implementations, the third temperature value may be approximately room temperature, such as, e.g., 25° C.

At block 750, in the second stage, method 700 may predict one or more second coefficients for each ring oscillator in the second set based on the second constant and the correlation. At block 760, in the second stage, method 700 may derive a temperature dependence based on the single operating frequency using the one or more second coefficients and the second constant for each of the second set of ring oscillators. Also, in the second stage, method 700 may derive (or deduce) the temperature dependence based on the third operating frequency using the one or more second coefficients and the second constant for each of the second set of ring oscillators.

Also, method 700 may use the temperature dependence to calibrate the temperature sensor. In some implementations, the temperature dependence may be determined by using a linear equation, which is derived or deduced or made-up of the coefficients and the constant y=mx+C.

In various implementations, in reference to each ring oscillator, the temperature may be measured at approximately 25° C. and 55° C., and with a linear relationship defined between the operating temperature and the operating frequency, then a linear relationship may be used to extrapolate the temperature between −140° C. to 120° C. based on a single temperature measurement. As such, the temperature does not need to be between 25° C. and 55° C. for extrapolation to work, and once it is determined that the relationship is linear, the temperature may be extrapolated in either direction, e.g., above and below.

In various implementations, method 700 may be configured to train an artificial intelligence (AI) algorithm to implement block 720 using the AI algorithm to determine the one or more first coefficients and a first constant for each ring oscillator in the first set of ring oscillators, and/or also implement block 730 using the AI algorithm to determine the correlation between each of the one or more first coefficients and the first constant. Also, during an inference phase, method 700 may use the AI algorithm to derive a temperature dependence of the second set of ring oscillators based on the single operating frequency using the correlation.

In various implementations, method 700 may be configured to train an artificial intelligence (AI) algorithm to implement block 750 using the AI algorithm to determine the one more second coefficients, and/or also implement block 730 using the AI algorithm to determine the correlation and then using inference at the second stage.

It should be intended that the subject matter of the claims may not be limited to the implementations and illustrations provided herein, but include modified forms of those implementations including portions of implementations and combinations of elements of different implementations in accordance with the claims. It should be appreciated that in the development of any such implementation, as in any engineering or design project, numerous implementation-specific decisions should be made to achieve developers' specific goals, such as compliance with system-related and business related constraints, which may vary from one implementation to another. Moreover, it should be appreciated that such a development effort may be complex and time consuming, but would nevertheless be a routine undertaking of design, fabrication, and manufacture for those of ordinary skill having benefit of this disclosure.

Described herein are various implementations of a method with multiple stages including a first stage and a second stage. In the first stage, the method may acquire operating frequencies for a first set of ring oscillators disposed in a first integrated circuit, wherein the operating frequencies are acquired at pre-determined temperatures with a constant voltage. Also, in the first stage, the method may determine one or more first coefficients and a first constant for each ring oscillator in the first set, wherein the one or more first coefficients and the first constant define a relationship between each operating temperature and each operating frequency using the acquired operating frequencies. Also, in the first stage, the method may determine a correlation between each of the first coefficients and the first constant. Also, in the second stage, the method may acquire a single operating frequency for each of a second set of ring oscillators in a second integrated circuit at a single pre-determined temperature so as to determine a second constant. Also, in the second stage, the method may predict one or more second coefficients for each ring oscillator in the second set based on the second constant and the correlation. Also, in the second stage, the method may derive a temperature dependence based on the single operating frequency using the one or more second coefficients and the second constant for each of the second set of ring oscillators.

Described herein are various implementations of a device comprising a digital temperature analyzer with a memory circuit and an arithmetic block. The memory circuit may include a look-up table configured to store one or more first coefficients and a first constant for each ring oscillator, wherein the one or more first coefficients and first constant are used to define a relationship between operating temperatures and operating frequencies based on previously acquired operating frequencies at pre-determined temperatures with a constant voltage for a first set of ring oscillators. Also, the arithmetic block may perform a calibration by acquiring a single operating frequency for each of a second set of ring oscillators at a single pre-determined temperature so as to determine a second constant and based on the second constant applies the one or more first coefficients and the first constant from the look-up table so as to derive a temperature.

Described herein are various implementations of a system having a CPU core and a digital temperature analyzer. The CPU core may have a plurality of ring oscillators disposed in different zones of the CPU core, and the digital temperature analyzer may be disposed external to the CPU core. Also, each ring oscillator uses the digital temperature analyzer independently. Also, the system may have a load drop-out unit (LDO) that controls a supply voltage provided to each ring oscillator. Also, the system may have a logic block configured to select a ring oscillator from the plurality of the ring oscillators that is using the digital temperature analyzer.

Reference has been made in detail to various implementations, examples of which are illustrated in the accompanying drawings and figures. In the following detailed description, numerous specific details are set forth to provide a thorough understanding of the disclosure provided herein. However, the disclosure provided herein may be practiced without these specific details. In other instances, various well-known methods, procedures, components, circuits and networks have not been described in detail so as not to unnecessarily obscure details of the embodiments.

It should also be understood that, although the terms first, second, etc. may be used herein to describe various elements, these elements should not be limited by these terms. These terms are only used to distinguish one element from another. For example, a first element could be termed a second element, and, similarly, a second element could be termed a first element. The first element and the second element are both elements, respectively, but they are not to be considered the same element.

The terminology used in the description of the disclosure provided herein is for the purpose of describing particular implementations and is not intended to limit the disclosure provided herein. As used in the description of the disclosure provided herein and appended claims, the singular forms “a,” “an,” and “the” are intended to include the plural forms as well, unless the context clearly indicates otherwise. The term “and/or” as used herein refers to and encompasses any and all possible combinations of one or more of the associated listed items. The terms “includes,” “including,” “comprises,” and/or “comprising,” when used in this specification, specify a presence of stated features, integers, steps, operations, elements, and/or components, but do not preclude the presence or addition of one or more other features, integers, steps, operations, elements, components and/or groups thereof.

As used herein, the term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. The terms “up” and “down”; “upper” and “lower”; “upwardly” and “downwardly”; “below” and “above”; and other similar terms indicating relative positions above or below a given point or element may be used in connection with some implementations of various technologies described herein.

While the foregoing is directed to implementations of various related techniques described herein, other and further implementations may be devised in accordance with the disclosure herein, which may be determined by the claims that follow.

Although the subject matter has been described herein in language specific to structural features and/or methodological acts, it should be understood that the subject matter defined in the appended claims is not necessarily limited to the specific features or acts described above. Rather, specific features and acts described above are disclosed as example forms of implementing the claims.

What is claimed is:

1. A method comprising:
in a first stage, acquiring operating frequencies for a first set of ring oscillators disposed in a first integrated circuit, wherein the operating frequencies are acquired at pre-determined temperatures with a constant voltage;
in the first stage, determining one or more first coefficients and a first constant for each ring oscillator in the first set, wherein the one or more first coefficients and the first constant define a relationship between each operating temperature and each operating frequency using the acquired operating frequencies;
in the first stage, determining a correlation between each of the first coefficients and the first constant;
in a second stage, acquiring a single operating frequency for each of a second set of ring oscillators in a second integrated circuit at a single pre-determined temperature so as to determine a second constant;
in the second stage, predicting one or more second coefficients for each ring oscillator in the second set based on the second constant and the correlation; and
in the second stage, deriving a temperature dependence based on the single operating frequency using the one or more second coefficients and the second constant for each of the second set of ring oscillators.

2. The method of claim 1, wherein:
the first integrated circuit comprises one or more first integrated circuits, and
the second integrated circuit comprises one or more second integrated circuits.

3. The method of claim 1, wherein:
the pre-determined temperatures comprise at least a first pre-determined temperature and a second pre-determined temperature, and
the operating frequencies comprise at least a first operating frequency and a second operating frequency acquired at the first pre-determined temperature and the second pre-determined temperature and at the constant voltage.

4. The method of claim 1, wherein:
the single pre-determined temperature comprises a third pre-determined temperature,
the single operating frequency comprises a third operating frequency, and
in the second stage, the third operating frequency is acquired for each ring oscillator in the second set at the third pre-determined temperature so as to determine the second constant.

5. The method of claim 4, wherein:
in the second stage, deriving the temperature dependence is based on the third operating frequency using the one or more second coefficients and the second constant for each of the second set of ring oscillators.

6. The method of claim 1, wherein the relationship defined between the operating temperature and the operating frequency is linear or non-linear.

7. The method of claim 1, wherein the relationship defined between the operating temperature and the operating frequency is a linear relationship that is further defined by a slope and an intercept as a linear function to conduct measurements at only one temperature during the second stage.

8. The method of claim 1, wherein the first constant and the one or more first coefficients are used to correct for frequency variation between the one or more ring oscillators of the second set of ring oscillators in the second integrated circuits.

9. The method of claim 3, wherein the first pre-determined temperature is approximately room temperature of 25° C.

10. The method of claim 3, wherein the first pre-determined temperature is the same as the single pre-determined temperature.

11. The method of claim 1, further comprising:
training an artificial intelligence (AI) algorithm to implement:
determining the one or more first coefficients and a first constant for each ring oscillator in the first set of ring oscillators;
determining the correlation between each of the one or more first coefficients and the first constant; and
then during an inference phase, deriving a temperature dependence of the second set of ring oscillators based on the single operating frequency using the correlation.

12. The method of claim 1, wherein each ring oscillator of the second set is configured to operate as a temperature sensor.

13. The method of claim 12, further comprising:
using the temperature dependence to calibrate the temperature sensor.

14. A digital temperature analyzer comprising:
a memory circuit having a look-up table configured to store one or more first coefficients and a first constant for each ring oscillator, wherein the one or more first coefficients and first constant are used to define a relationship between operating temperatures and operating frequencies based on previously acquired operating frequencies at pre-determined temperatures with a constant voltage for a first set of ring oscillators; and
an arithmetic block that performs a calibration by acquiring a single operating frequency for each of a second set of ring oscillators at a single pre-determined temperature so as to determine a second constant and based on the second constant applies the one or more first coefficients and the first constant from the look-up table so as to derive a temperature.

15. The digital temperature analyzer of claim 14, wherein:
the pre-determined temperatures comprise at least a first pre-determined temperature and a second pre-determined temperature, and
the operating frequencies comprise at least a first operating frequency and a second operating frequency acquired at the first pre-determined temperature and the second pre-determined temperature and at the constant voltage.

16. A CPU core comprising:
a plurality of the ring oscillators disposed in different zones of the CPU core; and
the digital temperature analyzer as claimed in claim 14 disposed near or wraps around each of the ring oscillators.

17. The CPU core of claim 16, wherein the digital temperature analyzer uses a supply voltage that is controlled by controlling a CPU voltage used by the CPU core.

18. The CPU core of claim 17, wherein a selection of one or more the plurality of ring oscillators to supply the voltage from the CPU core is via a communication bus protocol.

19. A system comprising:
a CPU core comprising a plurality of the ring oscillators disposed in different zones of the CPU core; and
the digital temperature analyzer as claimed in claim 14 is disposed external to the CPU core;
wherein each ring oscillator uses the digital temperature analyzer independently;
a load drop-out unit (LDO) that controls a supply voltage provided to each ring oscillator; and
a logic block configured to select a ring oscillator from the plurality of the ring oscillators which is using the digital temperature analyzer.

20. The system of claim 19, further comprising:
a reference analog temperature sensor configured to provide an analog measured temperature; wherein the analog measured temperature is compared with a temperature measurement provided by each ring oscillator so as to determine whether each ring oscillator provides a correct measured temperature.
